(19) United States
(12) Patent Application Publication
(10) Pub. No.: US 2019/0381522 A1
(43) Pub. Date: Dec. 19, 2019

(54) FILM FORMING METHOD AND FILM FORMING DEVICE

(71) Applicant: OPTNICS PRECISION CO., LTD., Ashikaga-shi, Tochigi (JP)

(72) Inventor: Seichin KINUTA, Ashikaga-shi, Tochigi (JP)

(21) Appl. No.: 16/304,698

(22) PCT Filed: May 18, 2018
(86) PCT No.: PCT/JP2018/019373

§ 371 Date: Nov. 27, 2018

(30) Foreign Application Priority Data
May 23, 2017 (JP) 2017-102068

(51) Int. Cl. B05B 5/025; B05D 1/04; B05D 1/32; H01L 21/02; H01L 21/67; H01L 51/00; H01L 51/50; H01L 51/56; H05B 33/10

(52) U.S. Cl. CPC B05B 5/025; B05D 1/04; B05D 1/32; H01L 21/02631; H05B 33/10; H01L 51/0011; H01L 51/5012; H01L 51/56; H01L 21/67017

(57) ABSTRACT

A film forming method, including providing a substrate in a lower section of a chamber, providing a mask on the substrate via an insulating body, spraying charged fine particles of a film forming material into a space inside the chamber, applying a potential of an opposite polarity to that of the charged fine particles to the substrate and applying a potential of the same polarity as that of the charged fine particles to the mask so as to deposit the fine particles on the substrate and form a film.

### TECHNICAL FIELD

The present disclosure relates to a film forming method and a film forming device for manufacturing by forming organic electroluminescence (organic EL) films and the like.

### BACKGROUND ART

Film forming must be made at predetermined positions with good precision for RGB light emitting segments to realize color with current organic EL elements. Such film forming technology includes thin film forming methods in which a deposition mask is deployed, and wet processes in which inkjet methods, spray methods, spin coating methods, and printing methods such as gravure methods and transfer methods are employed.

However, since vapor deposition masks employed in vapor deposition methods are affected by temperature changes during vapor deposition, the mask has to be made from a material having a similar numerical value for the coefficient of thermal expansion to that of the film forming substrate. Masks are currently produced by etching Invar and Kovar nickel-iron alloys. However, segment precision and resolution are constrained by the limits of etching precision, making such masks unsuitable in products demanding higher resolution at better precision.

With conventional film forming devices for which vapor deposition methods are employed, as well as there being an increase in size of film forming substrates, the devices also adopt a structure in which the substrate is placed in an upper section, the vapor deposition mask is disposed below the substrate, and an organic film is evaporated below the vapor deposition mask. The center of the substrate inside such devices deforms downward under the weight of the substrate itself for large size substrates, causing the vapor deposition mask to deform as well. Positional misalignment and enlarged gaps due to being affected in this manner means that accurate patterning cannot be performed.

In printing methods employed in wet processes, the organic EL material employed is itself a liquid, and is thus affected by surface tension, resulting in issues of uneven color due to uneven in-segment thickness. In inkjet printing methods, particles of the ink need to have particle diameters of a size that allows the effects of air resistance in flight to be ignored. The size of one segment is thus said to be around four times that of one segment when employing a vapor deposition mask, and so inkjet methods are not suited for display panels requiring high resolution.

Japanese Patent Application Laid-Open (JP-A) No. 2001-353454 (Patent Document 1) discloses a film forming method in which a film forming material is converted into charged fine particles, and selected electrodes are formed where film forming should be performed on a substrate, and non-selected electrodes are formed where film forming should not be performed thereon. The film forming material is then deposited on the selected electrodes by changing the potentials of the selected electrodes and non-selected electrodes and applying a voltage of the opposite polarity to that of the charged fine particles to the selected electrodes.

### SUMMARY OF INVENTION

### Technical Problem

In the manufacturing method of Patent Document 1, it is difficult to form the selected electrodes and non-selected electrodes with good precision on the substrate.

In order to address the above issue, an object of the present disclosure is to provide a manufacturing method and a film forming device to form films by causing a film forming material to be deposited in a fine pattern on a substrate using a mask, without forming selected electrodes and non-selected electrodes.

### Solution to Problem

A film forming method according to a first aspect includes providing a substrate in a lower section of a chamber, providing a mask on the substrate via an insulating body, spraying charged fine particles of a film forming material into a space inside the chamber, applying a potential of an opposite polarity to that of the charged fine particles to the substrate and applying a potential of the same polarity as that of the charged fine particles to the mask so as to deposit the fine particles on the substrate and form a film.

According to this film forming method, due to employing a high precision mask (a vapor deposition mask disclosed in Japanese Patent No. 4401040, obtained by the present applicant), the fine particles of film forming material can be deposited on the substrate at high precision even for substrates of large display panels that are difficult to manufacture using vapor deposition methods. This enables films for organic EL RGB to be formed on a substrate to achieve high resolution segments without uneven color.

A second aspect is the film forming method according to the first aspect, wherein the substrate is formed from a transparent body.

This film forming method is effectively used for the production of color filters for liquid crystal displays by employing dyes, pigment inks, or the like.

A third aspect is the film forming method according to the first aspect or the second aspect wherein the insulating body is either an insulating layer covering the mask or an insulating spacer interposed between the mask and the substrate.

This film forming method enables electrical conductivity of the mask to be prevented by covering the mask with an insulating layer using electrocoating or by interposing an insulating spacer.

A fourth aspect is the film forming method according to the first aspect or the second aspect wherein, the insulating body is an insulating layer covering the mask, and projecting edges that project downward with acute angle tips are formed to the insulating layer at a periphery of a bottom face of the mask, such that the projecting edges make close contact with the substrate.

In this film forming method, the projecting edges that project downward with acute angle tips at the periphery of the bottom face of the mask make close contact with the substrate, so that the fine particles do not infiltrate under the mask during film forming. The fine particles are accordingly deposited on the substrate only at predetermined locations, enabling film forming to be achieved at a very high precision.

A fifth aspect is the film forming method according to the first aspect or the second aspect wherein the insulating body is an insulating layer covering the mask and an insulating spacer interposed between the mask and the substrate.

In this film forming method, due to the insulating spacer being present between the mask and the substrate, electrical conductivity of the mask can be prevented even in cases in which a large substrate is employed and cracks develop in the insulating layer due to the mask sagging under its own weight. This enables film forming to be achieved at a very high precision.

A sixth aspect is the film forming method according to any one aspect from out of the first to the fifth aspects wherein the film forming material is an organic EL material.

This film forming method enables film forming to be performed so as to achieve high precision placement of segments for emitting RGB light at predetermined positions on the substrate, and so is well suited to the realization of color with organic EL elements.

A seventh aspect is a film forming device employing the film forming method according to any one aspect from out of the first to the sixth aspects. The film forming device includes a fine particulization device that forms fine particles of film forming material at a predetermined particle diameter, an atomizer that transforms the fine particles from the fine particulization device into a mist that is sprayed into the chamber, a charging device that charges the fine particles entering the chamber, a substrate potential application device that applies a potential of an opposite polarity to that of the charged fine particles to the substrate, and a mask potential application device that applies a potential of the same polarity as that of the charged fine particles to the mask.

This film forming device is a device that is able to operate in a humidity free nitrogen atmosphere in a dry atmospheric pressure environment, and so enables manufacturing costs of the device to be kept low.

An eighth aspect is the film forming device according to the seventh aspect, wherein the atomizer is a fine particle generator, employing a piezoelectric device to vibrate the fine particles, and mesh nozzles.

This film forming device enables the particle diameter of the fine particles to be controlled and enables uniform particle diameters to be secured.

### Advantageous Effects

According to the present disclosure, fine particles of film forming material can be deposited with high precision on a substrate even for substrates of large display panels that are difficult to manufacture with vapor deposition methods. This enables films for organic EL RGB to be formed on a substrate to achieve high resolution segments without uneven color.

### BRIEF DESCRIPTION OF DRAWINGS

FIG. 1 is a schematic view illustrating a film forming device of an exemplary embodiment.

FIG. 2 is an enlarged cross-section of part of the film forming device illustrated in FIG. 1.

FIG. 3 is an enlarged cross-section of part of a modified example of a film forming device of an exemplary embodiment.

FIG. 4 is an enlarged cross-section of part of a modified example of a film forming device of an exemplary embodiment.

FIG. 5 is an enlarged cross-section of part of a modified example of a film forming device of an exemplary embodiment.

FIG. 6 is an enlarged cross-section of part of a modified example of a film forming device of an exemplary embodiment.

FIG. 7 is a circuit diagram illustrating an electrical circuit of a substrate potential application device and a mask potential application device.

### DESCRIPTION OF EMBODIMENTS

Detailed explanation follows regarding an exemplary embodiment of a film forming method and a film forming device of the present invention, with reference to the drawings.

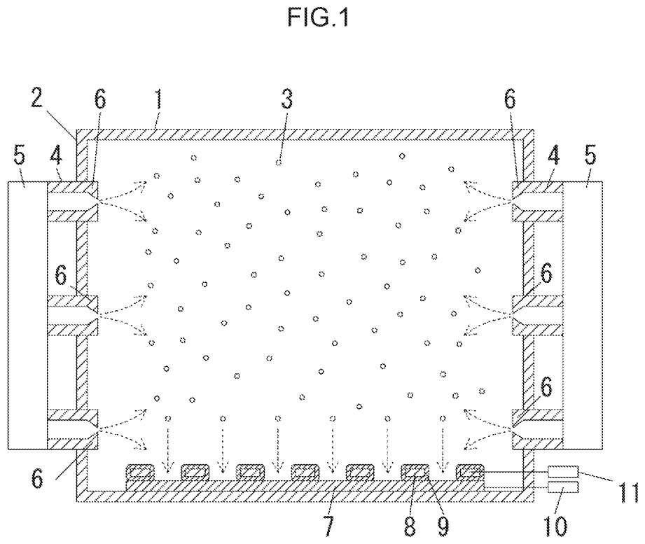

FIG. 1 illustrates a chamber 1 and an atomizer 5 including plural nozzles 4 that spray fine particles 3 of a film forming material into the chamber 1 from a side wall 2. The fine particles 3 have a uniform particle diameter of from 2 μm to 6 μm, and preferably of 3.3 μm±0.2 μm. The fine particles 3 are ejected into the chamber 1 by a piezoelectric device (not illustrated in the drawings) used to generate a spray from the atomizer 5 through the mesh-shaped nozzles 4 (having diameters of from 1 μm to 5 μm, and preferably produced to a precision of 2.5 μm±0.2 μm, for example). Charging devices 6 are provided to charge the fine particles 3 at a negative potential, for example.

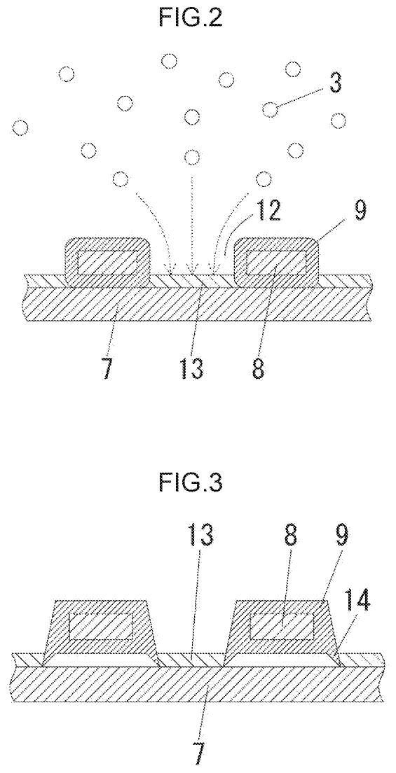

A substrate 7 formed from a transparent body is provided at the bottom of the chamber 1. A mask 8 manufactured by electroforming is provided on the substrate 7. A mask with a controllable coefficient of thermal expansion is employed as the mask 8 (a vapor deposition mask disclosed in Japanese Patent No. 4401040, obtained by the present applicant). In order to prevent electrical conductivity, the mask 8 is covered by an insulating layer 9 of a resin or the like formed using electrocoating, as illustrated in FIG. 2. Note that a cationic electrocoating resin (an epoxy-based resin or an epoxy-polyamide-based resin) is preferably employed in this electrocoating. Alternatively, instead of electrocoating, a coating of Parylene (para-xylene-based polymer) may be applied. The insulating layer 9 is an example of an insulator. This may employ a resin, for example 9T-Nylon, this being a type of semi-aromatic Nylon (Nylon is a registered trademark).

A substrate potential application device 10 applies the substrate 7 with a positive potential, this being the opposite polarity to that of the fine particles 3 charged with a negative potential. A mask potential application device 11 applies the mask 8 with a negative potential, this being the same polarity as that of the fine particles 3 charged with a negative potential. These devices will be described in detail later.

Explanation follows regarding the film forming method.

The fine particles 3 are ejected into the chamber 1 by the atomizer 5 with a uniform size particle diameter of, for example, 3.3 μm±0.2 μm.

The ejected fine particles 3 are, for example, charged to a negative potential by the charging devices 6. The substrate 7 is applied with a positive potential, this being the opposite polarity to that of the charged fine particles 3, by the substrate potential application device 10. The mask 8 is applied with a negative potential, this being the same polarity as that of the charged fine particles 3, by the mask potential application device 11. The mask 8 is covered by the insulating layer 9, and so the mask 8 and the substrate 7 are insulated from each other.

Accordingly, the fine particles 3 charged to a negative potential are repelled by the mask 8 applied with a negative potential of the same polarity thereto, and are attracted to the substrate 7 applied with positive potential of the opposite polarity thereto. The fine particles 3 thus pass through holes 12 in the mask 8 and are deposited on the substrate 7, thereby forming films 13 with good precision.

The mask 8 is then removed from the substrate 7 to obtain organic EL elements configured by the films 13.

The fine particles 3 with uniformly sized particle diameters of for example 3.3 μm±0.2 μm are ejected into the chamber 1. This has been confirmed to enable fine 10 μm squares to be obtained for the pattern coating dimensions with these particle diameters, far surpassing those using a vapor deposition mask.

Although the fine particles 3 are liquid when sprayed, since the fine particles 3 are sufficiently fine, with uniform particle diameters of, for example, 3.3 μm±0.2 μm, the fine particles 3 solidify at the same time as they are being deposited on the substrate 7, and uneven color resulting from surface tension or the like has been confirmed not to occur.

Moreover, since the substrate 7 is disposed at the lowest part of the chamber 1, and the mask 8 is disposed directly above the substrate 7, deformation and distortion of the substrate 7 due to gravity, such as arises in general vapor deposition methods, can be avoided even when employing large substrates.

The film forming device of the present disclosure is a device that operates in a humidity free nitrogen atmosphere in a dry atmospheric pressure environment, enabling manufacturing costs of the device to be kept low.

Forming the substrate 7 from a transparent body is effective for the production of color filters for liquid crystal displays when dyes, pigment inks, or the like are employed.

As illustrated in FIG. 3, ideally projecting edges 14 that project downward with acute angle tips are formed to the insulating layer 9 at the periphery of the bottom face of the mask 8, so as to place the projecting edges 14 in close contact with the substrate 7. The reason for adopting such a configuration is so that, during film forming, the fine particles 3 do not burrow under the mask 8 due to the close contact achieved at the acute angles of the projecting edges 14 with the substrate 7 at the periphery of the bottom face of the mask 8. This enables the fine particles 3 to be deposited on the substrate 7 only at predetermined locations, enabling the films 13 to be obtained with very high precision.

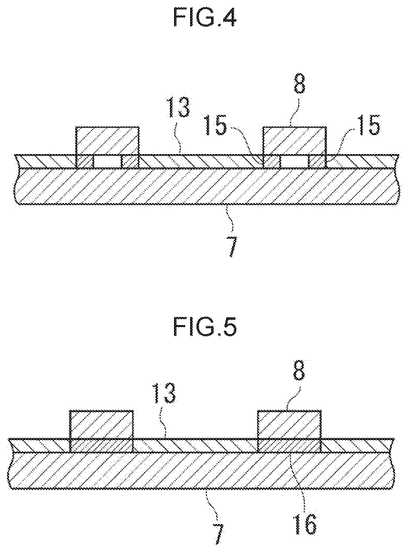

As illustrated in FIG. 4, in cases in which the mask 8 is not covered with an insulating layer, the mask 8 is provided with insulating spacers 15, serving as an example of insulating bodies, interposed above the substrate 7. The insulating spacers 15 are disposed at both ends of the bottom face of each element of the mask 8 so as to be disposed between the mask 8 and the substrate 7. The material employed for the insulating spacers 15 is preferably 9T Nylon (Nylon is a registered trademark), polyether ether ketone (PEEK), or a silicone resin which have excellent heat resistance, insulating properties, and ease of processing. The insulating spacers 15 enable the mask 8 and the substrate 7 to be completely insulated from each other even without covering the mask 8 with an insulating layer.

The insulating body may be configured by the insulating spacers 16 that cover the entire bottom face of the mask 8, as illustrated in FIG. 5.

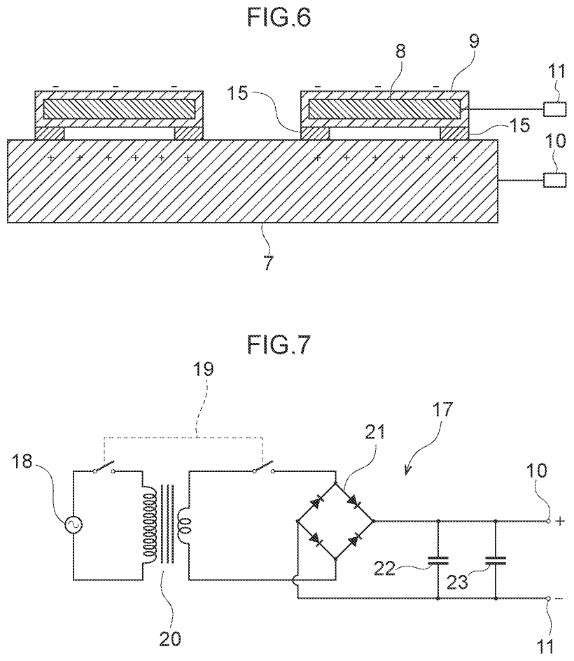

Insulating spacers 15 may be interposed between the substrate 7 and a mask 8 that has been covered by an insulating layer 9, as illustrated in FIG. 6.

When the substrate 7 employed is small, any configuration from out of a configuration in which the mask 8 is covered by the insulating layer 9 (FIG. 2, FIG. 3), a configuration in which the insulating spacers 15 are interposed between the mask 8 and the substrate 7 (FIG. 4), or a configuration in which the insulating spacers 16 are interposed between the mask 8 and the substrate 7 (FIG. 5). A configuration in which the mask 8 is covered by the insulating layer 9 (FIG. 2, FIG. 3) is preferable from the perspective of mass production.

When the substrate 7 employed is large, cracks might develop in the insulating layer 9 due to the mask 8 sagging under its own weight. Accordingly, a configuration in which the mask 8 is covered by the insulating layer 9 and the insulating spacers 15 are interposed between the mask 8 and the substrate 7 (FIG. 6) is preferable, and this enables films 13 to be obtained with very high precision.

The thickness of the insulating layer 9 or the insulating spacers 15 is set in consideration of the temperature inside the chamber 1 and the production line speed. Productivity suffers if the thickness thereof is 25 μm or less. The thickness is preferably from 40 μm to 60 μm in consideration of ease of production, productivity, and mechanical strength.

FIG. 7 illustrates an electrical circuit 17 used to apply voltages to the substrate potential application device 10 and the mask potential application device 11. The electrical circuit 17 is a rectifier circuit that converts alternating current to direct current. AC at 100V supplied from an alternating current power source 18 is converted to AC at from 2V to 10V by a transformer 20 when an interlock switch 19 is switched ON. The alternating current is converted into direct current by a bridge circuit 21 employing four diodes, and is then converted into a ripple-free direct current by a smoothing capacitor 22 and charged into an electrical double layer capacitor 23. The electrostatic capacitance of the capacitor 22 is from 200 μF to 300 μF. The anode side of the direct current charged in the electrical double layer capacitor 23 is connected to the substrate potential application device 10, and the cathode side thereof is connected to the mask potential application device 11.

The electrical double layer capacitor 23 (EDLC) referred to here is a large high capacitance capacitor with an electrostatic capacitance of from 50 F to 100 F. The electrical double layer capacitor 23 has a capacitance of 10⁶ to 10⁸ times that of a conventional aluminum electrolytic capacitor.

The production of large displays, such as 2 m×1.5 m displays, has recently been increasing. A certain amount of time is required to apply an electrostatic charge to large substrates and masks corresponding to such large displays. A large high capacitance electrical double layer capacitor (EDLC) is accordingly preferably employed in order to improve production line speeds. In the present exemplary embodiment, employing the electrical double layer capacitor 23 such as that described above enables electrostatic charge to be charged into and discharged from large substrates and masks in an instant.

The entire disclosure of Japanese Patent Application No. 2017-102068, filed on May 23, 2017, is incorporated by reference in the present specification.

All cited documents, patent applications, and technical standards mentioned in the present specification are incorporated by reference in the present specification to the same extent as if each individual cited document, patent application, or technical standard was specifically and individually indicated to be incorporated by reference.

1. A film forming method, comprising:
providing a substrate in a lower section of a chamber;
providing a mask on the substrate via an insulating body;
spraying charged fine particles of a film forming material into a space inside the chamber by a spraying device;
applying a potential of an opposite polarity to that of the charged fine particles to the substrate and applying a potential of the same polarity as that of the charged fine particles to the mask so as to deposit the fine particles on the substrate and form a film,
wherein a fine particulization device that comprises a piezoelectric device to vibrate the fine particles, and mesh nozzles, is used as the spraying device.

2. The film forming method of claim 1, wherein the substrate is formed from a transparent body.

3. The film forming method of claim 1, wherein the insulating body is either an insulating layer covering the mask or an insulating spacer interposed between the mask and the substrate.

4. The film forming method of claim 1, wherein:
the insulating body comprises an insulating layer covering the mask; and
projecting edges that project downward with acute angle tips are formed at the insulating layer at a periphery of a bottom face of the mask, such that the projecting edges make close contact with the substrate.

5. The film forming method of claim 1, wherein the insulating body is an insulating layer covering the mask and an insulating spacer interposed between the mask and the substrate.

6. The film forming method of claim 1, wherein the film forming material is an organic EL material.

7. A film forming device employed in the film forming method of claim 1, the film forming device comprising:
an atomizer that forms the fine particles of the film forming material at a predetermined particle diameter and sprays the fine particles into the chamber;
a charging device that charges the fine particles entering the chamber;
a substrate potential application device that applies a potential of an opposite polarity to that of the charged fine particles to the substrate; and
a mask potential application device that applies a potential of the same polarity as that of the charged fine particles to the mask, wherein
the atomizer is a fine particulization device that comprises a piezoelectric device to vibrate the fine particles, and mesh nozzles.

8. (canceled)
